(19) United States
(12) Patent Application Publication
(10) Pub. No.: US 2023/0165112 A1
(43) Pub. Date: May 25, 2023

(54) DISPLAY SUBSTRATE AND METHOD OF MANUFACTURING THE SAME, DISPLAY APPARATUS AND MASK

(71) Applicants: CHENGDU BOE OPTOELECTRONICS TECHNOLOGY CO., LTD., Sichuan (CN); BOE TECHNOLOGY GROUP CO., LTD., Beijing (CN)

(72) Inventors: Fuqiang YANG, Beijing (CN); Fan HE, Beijing (CN); Kemeng TONG, Beijing (CN); Cong FAN, Beijing (CN)

(73) Assignees: CHENGDU BOE OPTOELECTRONICS TECHNOLOGY CO., LTD., Sichuan (CN); BOE TECHNOLOGY GROUP CO., LTD., Beijing (CN)

(21) Appl. No.: 17/630,838

(22) PCT Filed: Jan. 28, 2021
(86) PCT No.: PCT/CN2021/074238

§ 371 Date: Jan. 27, 2022

(51) Int. Cl. H10K 59/80; H10K 59/12; H10K 59/131

(52) U.S. Cl. CPC H10K 59/87; H10K 59/1201; H10K 59/131

(57) ABSTRACT

A display substrate includes a base, and a circuit structure layer, a light-emitting device layer, and an encapsulation layer that are sequentially disposed on a side of the base. The encapsulation layer is configured to encapsulate the circuit structure layer and the light-emitting device layer on the base, and partial region(s) of the encapsulation layer is recessed toward a side of the encapsulation layer proximate to the base to form at least one depression. The display substrate further includes a filler layer, and the filler layer is filled in the at least one depression.

### CROSS-REFERENCE TO RELATED APPLICATION

This application is a national phase entry under 35 USC 371 of International Patent Application No. PCT/CN2021/074238, filed on Jan. 28, 2021, which is incorporated herein by reference in its entirety.

### TECHNICAL FIELD

The present disclosure relates to the field of display technologies, and in particular, to a display substrate and a method of manufacturing the same, a display apparatus and a mask.

### BACKGROUND

With the continuous development of touch technologies, most display apparatuses such as mobile phones and tablet computers have touch functions. In this type of display apparatus, a touch function layer is usually fabricated using a flexible multi-layer on cell (FMLOC) process. For example, a metal mesh structure is directly fabricated on an encapsulation layer of the display apparatus to achieve the touch function.

### SUMMARY

In an aspect, a display substrate is provided. The display substrate includes a base, and a circuit structure layer, a light-emitting device layer, and an encapsulation layer that are sequentially disposed on a side of the base. The encapsulation layer is configured to encapsulate the circuit structure layer and the light-emitting device layer on the base, and partial region(s) of the encapsulation layer are recessed toward a side of the encapsulation layer proximate to the base to form at least one depression. The display substrate further includes a filler layer, and the filler layer is filled in the at least one depression.

In some embodiments, the display substrate has a display area and a peripheral area located on at least one side of the display area. The circuit structure layer includes a first metal layer and a first insulating layer. The first metal layer includes at least two first metal wires located in the peripheral area. The at least two first metal wires extend along a direction parallel to an interface between the display area and the peripheral area, and the at least two first metal wires are spaced apart in a direction perpendicular to the interface. The first insulating layer includes at least two first insulating portions located in the peripheral area, each first insulating portion covers a first metal wire, and a first sub-opening is provided between two adjacent first insulating portions. A region of the encapsulation layer corresponding to the first sub-opening is recessed toward a side of the encapsulation layer proximate to the base to form a first depression in the at least one depression, and the filler layer includes a first filler portion filled in the first depression.

In some embodiments, the display substrate has a display area and a peripheral area located on at least one side of the display area. The circuit structure layer includes a first metal layer and a first insulating layer. The first metal layer includes at least two first metal wires located in the peripheral area. The at least two first metal wires extend along a direction parallel to an interface between the display area and the peripheral area, and the at least two first metal wires are spaced apart in a direction perpendicular to the interface. The first insulating layer includes at least two first insulating portions located in the peripheral area, each first insulating portion covers a first metal wire, and a first sub-opening is provided between two adjacent first insulating portions. The circuit structure layer further includes a second metal layer and a second insulating layer. The second metal layer includes at least two second metal wires located in the peripheral area, and each second metal wire is disposed on a surface of one first insulating portion away from the base. The second insulating layer includes at least two second insulating portions located in the peripheral area, each second insulating portion covers a second metal wire, and a second sub-opening that exposes the first sub-opening is provided between two adjacent second insulating portions. Regions of the encapsulation layer corresponding to the second sub-opening and the first sub-opening are recessed toward a side of the encapsulation layer proximate to the base to form a first depression, and the filler layer includes a first filler portion filled in the first depression.

In some embodiments, the peripheral area includes a bending area located on a side of the display area. The circuit structure layer further includes a third metal layer and a third insulating layer that are located in the bending area and sequentially disposed on the side of the base. The third metal layer includes at least one conductive connection portion. The third insulating layer covers the at least one conductive connection portion, and at least two first via holes that expose the at least one conductive connection portion are provided in the third insulating layer. The second metal layer further includes at least two third metal wires located in the bending area. The at least two third metal wires all extend along a direction pointing to the bending area from the display area, the at least two third metal wires are spaced apart in a direction perpendicular to an interface between the display area and the bending area, and two adjacent third metal wires are electrically connected to a conductive connection portion through two first via holes in the third insulating layer. The second insulating layer further includes at least two third insulating portions, each third insulating portion covers a third metal wire, and a second opening is provided between two adjacent third insulating portions. A region of the encapsulation layer corresponding to the second opening is recessed toward a side of the encapsulation layer proximate to the base to form a second depression in the at least one depression, and the filler layer includes a second filler portion filled in the second depression.

In some embodiments, the peripheral area includes a bending area located on a side of the display area, the circuit structure layer further includes a third metal layer and a third insulating layer that are located in the bending area and sequentially disposed on the side of the base. The third metal layer includes at least two conductive connection portion. The third insulating layer includes at least two fourth insulating portions, a fourth insulating portion covers a conductive connection portion, and a third opening is formed between two adjacent fourth insulating portions. At least two first via holes that expose a conductive connection portion are provided in a corresponding fourth insulating portion. The second metal layer further includes at least two third metal wires located in the bending area. The at least two third metal wires all extend along a direction pointing to the bending area from the display area, the at least two third metal wires are spaced apart in a direction perpendicular to an interface between the display area and the bending area. The first insulating layer further includes at least two fifth insulating portions, a fifth insulating portion covers a third opening and portions, proximate to the third opening, of two fourth insulating portions adjacent to the third opening. The fifth insulating portion is provided with two second via holes therein that respectively expose two first via holes, each third metal wire is located on a surface of a fifth insulating portion away from the base, and a third metal wire is connected to two conductive connection portions through two second via holes and two first via holes. The second insulating layer further includes at least two third insulating portions. Each third insulating portion covers a third metal wire, and a second opening is provided between two adjacent third insulating portions. A region of the encapsulation layer corresponding to the second opening is recessed toward a side of the encapsulation layer proximate to the base to form a second depression in the at least one depression, and the filler layer includes a second filler portion filled in the second depression.

In some embodiments, the display substrate has a display area and a peripheral area located on at least one side of the display area; and the peripheral area includes a bending area located on a side of the display area. The circuit structure layer includes: a third metal layer and a third insulating layer that are located in the bending area and sequentially disposed on the side of the base; the third metal layer including at least one conductive connection portion; the third insulating layer covering the at least one conductive connection portion, and at least two first via holes that expose the at least one conductive connection portion being provided in the third insulating layer; a second metal layer including at least two third metal wires located in the bending area, the at least two third metal wires all extending along a direction pointing to the bending area from the display area, the at least two third metal wires being spaced apart in a direction perpendicular to an interface between the display area and the bending area, and two adjacent third metal wires being electrically connected to a conductive connection portion through two first via holes in the third insulating layer; and a second insulating layer including at least two third insulating portions, each third insulating portion covering a third metal wire, and a second opening being provided between two adjacent third insulating portions. A region of the encapsulation layer corresponding to the second opening is recessed toward a side of the encapsulation layer proximate to the base to form a second depression in the at least one depression, and the filler layer includes a second filler portion filled in the second depression.

In some embodiments, the display substrate has a display area and a peripheral area located on at least one side of the display area. The peripheral area includes a bending area located on a side of the display area. The circuit structure layer includes: a third metal layer and a third insulating layer that are located in the bending area and sequentially disposed on the side of the base; the third metal layer including at least two conductive connection portion; the third insulating layer including at least two fourth insulating portions, a fourth insulating portion covering a conductive connection portion, and a third opening being formed among two adjacent fourth insulating portions and the base; a second metal layer including at least two third metal wires located in the bending area, the at least two third metal wires all extending along a direction pointing to the bending area from the display area, and the at least two third metal wires being spaced apart in a direction perpendicular to an interface between the display area and the bending area; a first insulating layer including at least two fifth insulating portions, a fifth insulating portion covering a third opening and portions, proximate to the third opening, of two fourth insulating portions adjacent to the third opening; and the fifth insulating portion being provided with two second via holes therein that respectively expose two first via holes; each third metal wire being located on a surface of a fifth insulating portion away from the base, and a third metal wire being connected to two conductive connection portions through two second via holes and two first via holes; and a second insulating layer including at least two third insulating portions, each third insulating portion covering a third metal wire, and a second opening being provided between two adjacent third insulating portions. A region of the encapsulation layer corresponding to the second opening is recessed toward a side of the encapsulation layer proximate to the base to form a second depression in the at least one depression, and the filler layer includes a second filler portion filled in the second depression.

In some embodiments, each third insulating portion further covers a fifth insulating portion.

In some embodiments, the display substrate has two second openings, and two regions of the encapsulation layer corresponding to the two second openings are separately recessed toward a side of the encapsulation layer proximate to the base to form two second depressions, and the filler layer includes two second filler portions filled in the two second depressions.

In some embodiments, the display substrate has a display area, an opening area at least partially surrounded by the display area, and a separation area located between the opening area and the display area. The display substrate further includes a first dam located in the separation area and between the base and the encapsulation layer, and the first dam being disposed around the opening area; and a second dam located in the separation area and between the base and the encapsulation layer, the second dam being disposed around the opening area, and the second dam being located between the first dam and the opening area. A region of the encapsulation layer located on a side of the second dam proximate to the opening area is recessed toward a side of the encapsulation layer proximate to the base to form a third depression in the at least one depression, and the filler layer includes a third filler portion filled in the third depression; and/or, a region of the encapsulation layer located on a side of the second dam proximate to the display area is recessed toward a side of the encapsulation layer proximate to the base to form a fourth depression in the at least one depression, and the filler layer includes a fourth filler portion filled in the fourth depression.

In some embodiments, a surface of the filler layer away from the base is flush with or substantially flush with a surface of the encapsulation layer away from the base.

In some embodiments, the display substrate further includes a first wiring layer that covers at least a portion of the surface of the filler layer away from the base and a portion of the surface of the encapsulation layer away from the base.

In some embodiments, the first wiring layer includes a plurality of first touch electrodes and a plurality of touch sub-electrodes in a plurality of second touch electrodes. Each first touch electrode is an integrated structure, the plurality of touch sub-electrodes are arranged in an array, and two adjacent touch sub-electrodes located in a second touch electrode are separated by a first touch electrode. The display substrate further includes a fourth insulating layer having a plurality of third via holes, and a second wiring layer including a plurality of connection portions. Each connection portion electrically connects two adjacent touch sub-electrodes in a second touch electrode through at least two third via holes, and an orthogonal projection of the connection portion on the base and an orthogonal projection of the first touch electrode on the base have an intersection region therebetween. The first wiring layer further includes a plurality of touch leads, and each touch lead is electrically connected to a first touch electrode or a second touch electrode. Components of at least one type in the plurality of first touch electrodes, the plurality of touch sub-electrodes, and the plurality of touch leads cover at least the portion of the surface of the filler layer away from the base.

In another aspect, a display apparatus is provided. The display apparatus includes the display substrate as described in any of the above embodiments.

In yet another aspect, a mask for manufacturing the filler layer of the display substrate as described in any of the above embodiments is provided. The mask includes a mask body and at least one light-transmitting portion disposed in the mask body, and each light-transmitting portion is configured to allow light to pass through to enter at least one depression in the display substrate.

In yet another aspect, a method of manufacturing a display substrate is provided. The method includes: providing a base; forming a circuit structure layer, a light-emitting device layer, and an encapsulation layer sequentially on a side of the base, the encapsulation layer encapsulating the circuit structure layer and the light-emitting device layer on the base, and partial region(s) of the encapsulation layer being recessed toward a side of the encapsulation layer proximate to the base to form at least one depression; placing a filler material into the at least one depression; exposing the filler material using the mask as described in any of the above embodiments and developing the exposed filler material, so as to form a filler layer.

In some embodiments, the method further includes: forming a touch function layer on a surface of the filler layer and the encapsulation layer as a whole away from the base, and the touch function layer including a first wiring layer, a fourth insulating layer, and a second wiring layer that are sequentially away from the base.

### BRIEF DESCRIPTION OF THE DRAWINGS

In order to describe technical solutions in the present disclosure more clearly, accompanying drawings to be used in some embodiments of the present disclosure will be introduced briefly below. However, the accompanying drawings to be described below are merely accompanying drawings of some embodiments of the present disclosure, and a person of ordinary skill in the art can obtain other drawings according to these drawings. In addition, the accompanying drawings to be described below may be regarded as schematic diagrams, but are not limitations on an actual size of a product, an actual process of a method and an actual timing of a signal involved in the embodiments of the present disclosure.

FIG. 1 is a diagram showing a structure of a display substrate, in accordance with some embodiments;

FIG. 2 is a cross-sectional view of the display substrate in FIG. 1 taken along A-A′ direction;

FIG. 3 is a cross-sectional view of the display substrate in FIG. 1 taken along B-B′ direction;

FIG. 4 is another cross-sectional view of the display substrate in FIG. 1 taken along the B-B′ direction;

FIG. 5 is a cross-sectional view of the display substrate in FIG. 1 taken along C-C′ direction;

FIG. 6 is another cross-sectional view of the display substrate in FIG. 1 taken along the C-C′ direction;

FIG. 7 is a cross-sectional view of the display substrate in FIG. 1 taken along D-D′ direction;

FIG. 8 is a diagram showing a structure of another display substrate, in accordance with some embodiments;

FIG. 9 is a top view of yet another display substrate, in accordance with some embodiments;

FIG. 10 is a cross-sectional view of the display substrate in FIG. 9 taken along E-E′ direction;

FIG. 11 is a diagram showing a structure of a mask, in accordance with some embodiments;

FIG. 12 is a flow diagram of a method of manufacturing a display substrate, in accordance with some embodiments;

FIG. 13 is a flow diagram of another method of manufacturing a display substrate, in accordance with some embodiments; and

FIG. 14 is a diagram showing a structure of a display apparatus, in accordance with some embodiments.

### DETAILED DESCRIPTION

Technical solutions in some embodiments of the present disclosure will be described clearly and completely below with reference to the accompanying drawings. However, the described embodiments are merely some but not all embodiments of the present disclosure. All other embodiments obtained on a basis of the embodiments of the present disclosure by a person of ordinary skill in the art shall be included in the protection scope of the present disclosure.

Unless the context requires otherwise, throughout the description and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, specific features, structures, materials, or characteristics may be included in any one or more embodiments or examples in any suitable manner.

Hereinafter, the terms “first” and “second” are used for descriptive purposes only, and are not to be construed as indicating or implying relative importance or implicitly indicating the number of indicated technical features. Thus, a feature defined with “first” or “second” may explicitly or implicitly include one or more of the features. In the description of the embodiments of the present disclosure, the term “a plurality of”, “the plurality of” or “multiple” means two or more unless otherwise specified.

In the description of some embodiments, the terms such as “coupled” and “connected” and derivatives thereof may be used. For example, the term “connected” may be used in the description of some embodiments to indicate that two or more components are in direct physical or electrical contact with each other. For another example, the term “coupled” may be used in the description of some embodiments to indicate that two or more components are in direct physical or electrical contact. However, the term “coupled” or “communicatively coupled” may also mean that two or more components are not in direct contact with each other, but still cooperate or interact with each other. The embodiments disclosed herein are not necessarily limited to the content herein.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The term “approximately” or “substantially” as used herein includes a stated value and an average value within an acceptable range of deviation of a particular value. The acceptable range of deviation is determined by a person of ordinary skill in the art in view of the measurement in question and the error associated with the measurement of a particular quantity (i.e., the limitations of the measurement system).

In this context, “being disposed in a same layer” refers to a film layer formed for forming a specific pattern by using a same film-forming process, and then a layer structure formed through a single patterning process by using a same mask. Depending on different specific patterns, a same patterning process may include multiple exposure, development or etching processes, and the specific patterns in the formed layer structure may be continuous or discontinuous, and these specific patterns may also be at different heights or have different thicknesses.

Exemplary embodiments are described herein with reference to sectional views and/or plan views as idealized exemplary drawings. In the accompanying drawings, thicknesses of layers and regions are enlarged for clarity. Thus, variations in shapes relative to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Therefore, the regions shown in the accompanying drawings are schematic in nature, and their shapes are not intended to show actual shapes of the regions in a device, and are not intended to limit the scope of the exemplary embodiments.

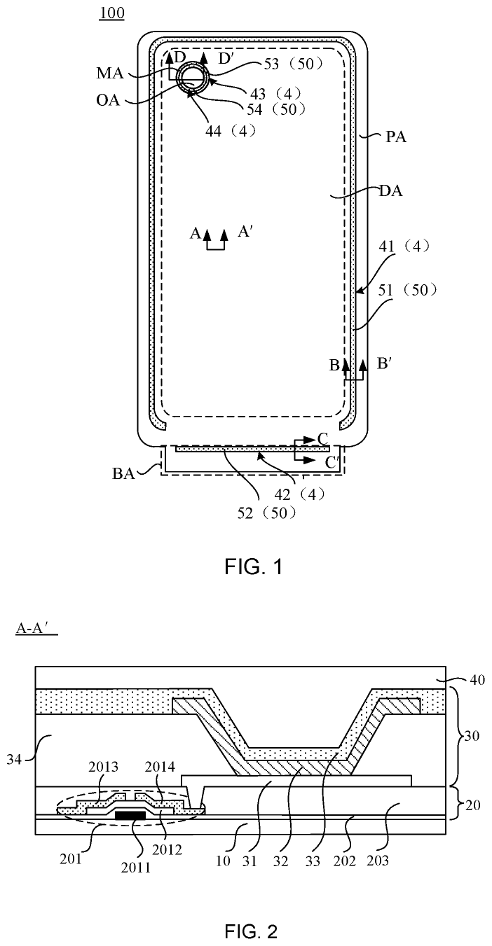

FIG. 1 is a diagram showing a structure of a display substrate, in accordance with some embodiments of the present disclosure; and FIG. 2 is a cross-sectional view of a position of a sub-pixel of the display substrate in FIG. 1 taken along A-A′ direction.

Referring to FIGS. 1 and 2, some embodiments of the present disclosure provide a display substrate 100. The display substrate 100 includes a base 10, and a circuit structure layer 20, a light-emitting device layer 30, an encapsulation layer 40, and a filler layer 50 that are sequentially disposed on a side of the base 10.

A material of the base 10 may be polyimide, glass, silicon substrate, etc.

For example, the light-emitting device layer 30 includes a plurality of light-emitting devices located in a display area DA. As shown in FIG. 2, a light-emitting device in each sub-pixel includes an anode 31, a light-emitting functional layer 32, and a cathode 33 that are sequentially away from the base 10. Cathodes 33 of the plurality of light-emitting devices may constitute a whole-layer structure or may be block structures, which is not limited in the present disclosure.

Based on this, as shown in FIG. 2, the light-emitting device layer 30 further includes a pixel defining layer 34. The pixel defining layer 34 includes a plurality of opening areas. A light-emitting functional layer 32 of a light-emitting device may be correspondingly provided in an opening area. In some examples, the light-emitting functional layer 32 includes a light-emitting layer. In some other examples, in addition to the light-emitting layer, the light-emitting functional layer 32 further includes one or more of an electron transport layer (abbreviated as ETL), an electron injection layer (abbreviated as EIL), a hole transport layer (abbreviated as HTL) and a hole injection layer (abbreviated as HIL).

For example, the circuit structure layer 20 includes a plurality of pixel circuits. As shown in FIG. 2, each pixel circuit at least includes one driving transistor 201. The driving transistor 201 includes a gate 2011, an active layer 2012, a source 2013, and a drain 2014. In addition, in some examples, as shown in FIG. 2, the circuit structure layer 20 further includes a gate insulating layer 202 that separates the gate 2011 from the active layer 2012, and a planarization layer 203 that covers the source 2013 and the drain 2014. The planarization layer is provided with via holes, and the anode 31 of the light-emitting device may be electrically connected to the drain 2014 through a via hole of the planarization layer 203, so that the pixel circuit may drive the light-emitting functional layer 32 to emit light.

Referring to FIGS. 1 to 4, the encapsulation layer 40 is configured to encapsulate the circuit structure layer 20 and the light-emitting device layer 30 on the base 10, and partial region(s) of the encapsulation layer 40 are recessed toward a side of the encapsulation layer 40 proximate to the base 10 to form at least one depression 4.

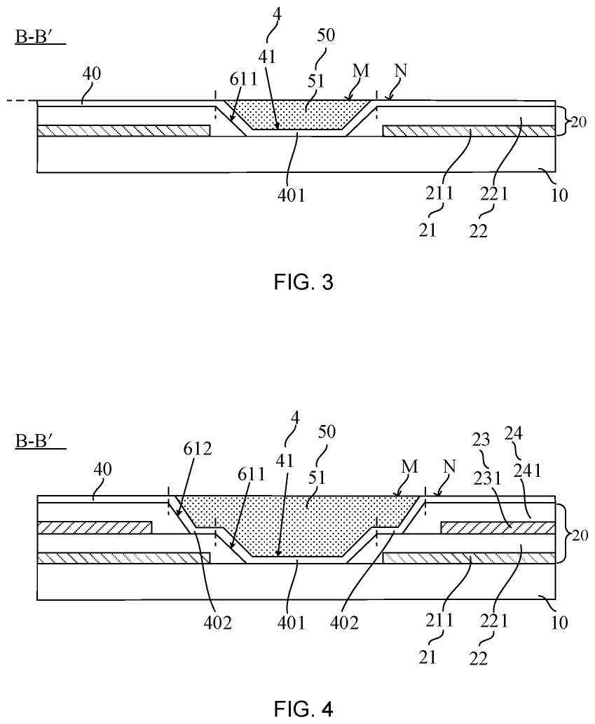

As shown in FIGS. 3 and 4, the filler layer 50 is filled in the at least one depression 4. According to the number of depressions 4 that are to be filled, the filler layer 50 may be divided into filler portions having a same number as the depressions 4 that are to be filled, and each filler portion is filled in a depression 4. For example, in an example shown in FIG. 1, a first filler portion 51 is filled in a first depression 41, a second filler portion 52 is filled in a second depression 42, a third filler portion 53 is filled in a third depression 43, and a fourth filler portion 54 is filled in a fourth depression 44.

The above “depressions 4 that are to be filled” may be all the depressions 4 in the display substrate 100, or may be part of all the depressions 4 (e.g., one or two or more than two depressions 4 among all the depressions 4). Therefore, shapes and the number of the filler portions may be flexibly adjusted according to specific positions and the number of the depressions 4 that are to be filled.

The filler layer 5 may be made of an organic insulating material, for example, polyimide.

It is worth noting that in a process of manufacturing a wiring layer on the encapsulation layer 40, a metal thin film needs to be manufactured on the encapsulation layer first, then a layer of photoresist is manufactured on the metal thin film, and a portion of the photoresist corresponding to a portion of the metal thin film which needs to be etched and removed is removed through exposure and development. However, it is found through research that, when the portion of the photoresist corresponding to the portion of the metal thin film which needs to be etched and removed is located on the depression 4, there may be a case where the portion of the photoresist is exposed and developed insufficiently. Therefore, a phenomenon of insufficient etching of the portion of the metal thin film which needs to be etched and removed may be caused, which may cause metal residues, resulting in a short-circuit between adjacent metal wires in the manufactured wiring layer.

In the display substrate 100 provided by some embodiments of the present disclosure, the filler layer 50 may be used to fill at least one depression 4 in the encapsulation layer 40. For example, as shown in FIGS. 3 to 7, a surface M of the filler layer 50 away from the base 10 and a portion N, not covered by the filler layer 50, of a surface of the encapsulation layer 40 away from the base 10 (this entirety is hereinafter referred to as a bearing surface) form a plane. In this way, in a subsequent process of manufacturing the wiring layer (e.g., touch lines in a touch function layer) on the encapsulation layer 40, a problem of insufficient etching of a portion of the metal thin film located in the depression 4 is not easy to occur, so that metal residues do not easily appear at this position, and the short circuit between adjacent metal wires in the manufactured wiring layer is not easily caused, which is therefore beneficial to improve a yield of the display substrate 100.

In some examples, as shown in FIGS. 3 to 6, the surface M of the filler layer 50 away from the base 10 is flush with the portion N, not covered by the filler layer 50, of the surface of the encapsulation layer 40 away from the base 10. That is, in this example, the filler layer 50 may fill up at least one depression 4, and for example, the plane described above may be formed. In this way, after the above metal wires are formed, the short-circuit phenomenon hardly occurs. In some other examples, as shown in FIG. 7, the surface M of the filler layer 50 away from the base 10 is substantially flush with the portion N, not covered by the filler layer 50, of the surface of the encapsulation layer 40 away from the base 10. Herein, “being substantially flush with” means that a height difference between the two surfaces is within an acceptable error range. For example, the height difference is less than a preset value, and the preset value may be in a range of, for example, approximately 0.8 μm to approximately 1 μm. For example, the preset value may be 0.8 μm, 0.9 μm, or 1 μm. In this way, after the above metal wires are formed, the short-circuit phenomenon hardly occurs.

In some examples, the filler layer 50 is filled in all the depressions 4 in the display substrate 100. In a case where the filler layer 50 is filled in all the depressions 4 in the display substrate 100, the bearing surface of the display substrate 100 that is used for bearing the metal thin film may be made flat, which is therefore beneficial to ameliorate the short-circuit problem easily occurring in the metal wires in the wiring layer. In addition, in some other examples, the filler layer 50 is filled in part of the depressions 4 in the display substrate 100. In this case, the number of filler portions and filling positions may also be set according to arrangement positions of the metal wires in the wiring layer. In this way, it is possible to ameliorate the short-circuit problem between adjacent metal wires due to metal residues in a targeted way.

In some embodiments, as shown in FIG. 1, the display substrate 100 has the display area DA and a peripheral area PA located on at least one side of the display area DA. For example, the peripheral area PA is located around the display area DA to completely surround the display area DA. For another example, the peripheral area PA may also be located on any one, two, or three sides of the display area DA. As for the display area DA, it can be substantially rectangular, circular, polygonal, etc., which is not limited herein.

Based on this, as shown in FIG. 3, the circuit structure layer 20 includes a first metal layer 21 and a first insulating layer 22.

The first metal layer 21 includes at least two first metal wires 211 located in the peripheral area PA. The at least two first metal wires 211 extend along a direction parallel to an interface between the display area DA and the peripheral area PA (i.e., a direction perpendicular to a plane of the paper in FIG. 3), and the at least two first metal wires 211 are spaced apart in a direction perpendicular to the interface (i.e., a direction from a left side to a right side or a direction from the right side to the left side in FIG. 3).

The first metal wire 211 may be a voltage signal line. The first metal wire 211 may be disposed in a same layer as the gate 2011 in FIG. 2. In this case, the first metal wire 211 is made of a same material as the gate 2011. Of course, in other examples, the first metal wire 211 may also be disposed in a same layer as another film layer, which is not limited in the present disclosure.

The first insulating layer 22 includes at least two first insulating portions 221 located in the peripheral area PA. Each first insulating portion 221 covers one first metal wire 211. A first sub-opening 611 is provided between two adjacent first insulating portions 221.

The first insulating layer 22 may be disposed in a same layer as the gate insulating layer 202. In this case, the first insulating layer 22 is made of a same material as the gate insulating layer 202. Of course, in other examples, the first insulating layer 22 may also be manufactured in a same layer as another film layer, which is not limited in the present disclosure.

A region 401 of the encapsulation layer 40 corresponding to the first sub-opening 611 is recessed toward a side of the encapsulation layer 40 proximate to the base 10 to form a first depression 41 in the at least one depression 4, and the filler layer 50 includes the first filler portion 51 filled in the first depression 41. The number of first depressions 41 is not limited. That is, the number of the first depressions 41 may be one, two or more. Correspondingly, the number of first filler portions 51 may also be one, two or more.

With this arrangement, in an aspect, water vapor may be prevented from permeating from a side of the first sub-opening 611 away from the display area DA to a side of the first sub-opening 611 proximate to the display area DA, thereby reducing a risk that a circuit structure in the display substrate 100 is eroded by water and oxygen; and in another aspect, since the first filler portion 51 is filled in the first depression 41, the bearing surface of the display substrate 100 located in the peripheral area PA may be made relatively flat, which may effectively ameliorate the short-circuit between adjacent metal wires in the wiring layer because of insufficient etching after the wiring layer is manufactured.

Based on some of the above embodiments, for example, as shown in FIG. 4, the circuit structure layer 20 further includes a second metal layer 23 and a second insulating layer 24.

The second metal layer 23 includes at least two second metal wires 231 located in the peripheral area PA, and each second metal wire 231 is disposed on a surface of one first insulating portion 221 away from the base 10.

The second metal wire 231 may also be a voltage signal line. In this case, the second metal wire 231 may be electrically connected to the first metal wire 211 through a via hole in the first insulating portion 221 to form a voltage signal line with a double-layer structure, which is beneficial to reduce a resistance of the voltage signal line. In addition, the second metal wire 231 may be disposed in a same layer as the source 2013 and the drain 2014 in FIG. 2. In this case, the second metal wire 231 is made of a same material as the source 2013 and the drain 2014. Of course, in other examples, the second metal wire 231 may also be disposed in a same layer as another film layer, which is not limited in the present disclosure.

The second insulating layer 24 includes at least two second insulating portions 241 located in the peripheral area PA. Each second insulating portion 241 covers one second metal wire 231. A second sub-opening 612 that exposes a first sub-opening 611 is provided between two adjacent second insulating portions. In some examples, in a direction perpendicular to the base 10, a sum of a depth of the first sub-opening 611 and a depth of the second sub-opening 612 may be approximately 4 μm.

The second insulating layer 24 may be disposed in a same layer as the planarization layer 203. In this case, the second insulating layer 24 is made of a same material as the planarization layer 203. Of course, in other examples, the second insulating layer 24 may also be manufactured in a same layer as another film layer, which is not limited in the present disclosure.

Regions of the encapsulation layer 40 corresponding to the second sub-opening 612 and the first sub-opening 611 (i.e., the region 401 and a region 402 in FIG. 4) are recessed toward a side of the encapsulation layer 40 proximate to the base 10 to form a first depression 41. In this case, the first depression 41 may be filled by a first filler portion 51 with a relatively large volume, so that the bearing surface of the display substrate 100 located in the peripheral area PA is relatively flat.

With this arrangement, in an aspect, water vapor may be prevented from permeating from a side of the first sub-opening 611 and the second sub-opening 612 as a whole away from the display area DA to a side of the first sub-opening 611 and the second sub-opening 612 as the whole proximate to the display area DA, thereby reducing the risk that the circuit structure in the display substrate 100 is eroded by water and oxygen; and in another aspect, since the first filler portion 51 is filled in the first depression 41, the bearing surface of the display substrate 100 located in the peripheral area PA may be made relatively flat, which may effectively ameliorate the short-circuit between adjacent metal wires in the wiring layer because of insufficient etching after the wiring layer is manufactured.

In some embodiments, as shown in FIG. 1, the peripheral area PA includes a bending area BA located on a side of the display area DA. For example, the bending area BA may be a portion of the peripheral area PA away from the display area DA. A portion of the display substrate 100 located in the bending area BA may be used such that a flexible circuit board is bonded thereon. In addition, by bending the portion of the display substrate 100 located in the bending area BA, it is beneficial to reduce a bezel of a display apparatus manufactured by adopting the display substrate 100.

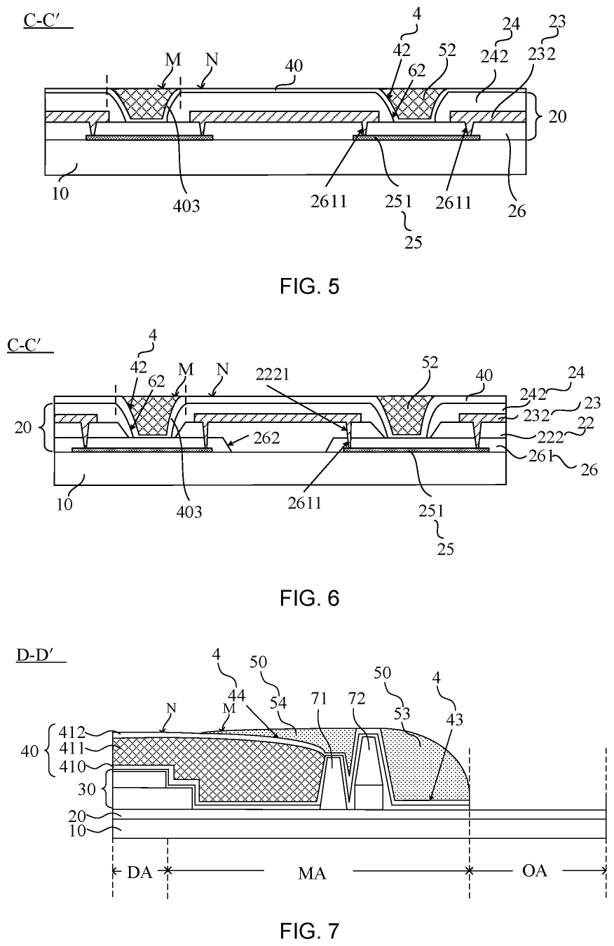

Based on this, as shown in FIG. 5, the circuit structure layer 20 further includes a third metal layer 25 and a third insulating layer 26 that are located in the bending area BA and sequentially disposed on the side of the base 10.

The third metal layer 25 includes at least one conductive connection portion 251. The third insulating layer 26 covers the at least one conductive connection portion 251, and at least two first via holes 2611 that expose the at least one conductive connection portion 251 are provided in the third insulating layer 26.

The second metal layer 23 further includes at least two third metal wires 232 located in the bending area BA. The at least two third metal wires 232 all extend along a direction pointing to the bending area BA from the display area DA. The at least two third metal wires 232 are spaced apart in a direction perpendicular to an interface between the display area DA and the bending area BA, and two adjacent third metal wires 232 are electrically connected to one conductive connection portion 251 through two first via holes 2611 in the third insulating layer 26. In this way, the third metal wires 232 and the conductive connection portion 251 that are alternately arranged are connected to form a signal line, and the signal line may be used to transmit a data voltage signal or a scanning voltage signal.

The second insulating layer 24 further includes at least two third insulating portions 242, each third insulating portion 242 covers one third metal wire 232, and a second opening 62 is provided between two adjacent third insulating portions 242. In some examples, in the direction perpendicular to the base 10, a depth of the second opening 62 may be approximately 4 μm.

A region 403 of the encapsulation layer 40 corresponding to the second opening 62 is recessed toward a side of the encapsulation layer 40 proximate to the base 10 to form the second depression 42 in the at least one depression 4, and the filler layer 50 includes the second filler portion 52 filled in the second depression 42. The number of second depressions 42 is not limited. That is, the number of the second depressions 42 may be one, two or more. Correspondingly, the number of second filler portions 52 may also be one, two or more.

With this arrangement, in an aspect, since the second opening 62 is provided, a bending stress subjected by the bending area BA is reduced when the bending area BA is bent, and there are advantages in that the bending area BA is bent easily, and after the bending, the film layers are not broken easily at this position. Moreover, since the third metal wires 232 and the conductive connection portion 251 are alternately arranged and connected to form the signal line, the signal line is not broken easily at this position. In another aspect, water vapor may be prevented from permeating from a side of the second opening 62 away from the display area DA to a side of the second opening 62 proximate to the display area DA, thereby reducing the risk that the circuit structure in the display substrate 100 is eroded by water and oxygen. In yet another aspect, since the second filler portion 52 is filled in the second depression 42, the bearing surface of the display substrate 100 located in the bending area BA may be made relatively flat, which may effectively ameliorate the short-circuit between adjacent metal wires in the wiring layer because of insufficient etching after the wiring layer is manufactured.

Based on this, for example, as shown in FIG. 6, the third insulating layer 26 includes at least two fourth insulating portions 261. One fourth insulating portion 261 covers one conductive connection portion 251, and a third opening 262 is formed between two adjacent fourth insulating portions 261. By providing the third opening 262, the portion of the display substrate 100 located in the bending area BA may be bent easily.

The first insulating layer 22 further includes at least two fifth insulating portions 222. A fifth insulating portion 222 covers a third opening 262 and portions, proximate to the third opening 262, of two fourth insulating portions 261 adjacent to the third opening 262. The fifth insulating portion 222 is provided with two second via holes 2221 therein that respectively expose two first via holes 2611. Each third metal wire 232 is located on a surface of one fifth insulating portion 222 away from the base 10, and a third metal wire 232 is connected to two conductive connection portions 251 through two second via holes 2221 and two first via holes 2611.

In this example, by providing the fifth insulating portions 222, a surface for bearing each third metal wire 232 is made flat, which is beneficial to improve a quality of the third metal wire 232, and is further beneficial to improve a signal transmission quality of the third metal wire 232.

For example, as shown in FIG. 6, each third insulating portion 242 further covers one fifth insulating portion 222. This helps to prevent water vapor from permeating into the third metal wire 232 to protect the third metal wire 232.

For example, as shown in FIG. 6, the display substrate 100 has two second openings 62. With this arrangement, a bending axis may be located between the two second openings 62. In this case, after the portion of the display substrate 100 located in the bending area BA is bent, stresses at both ends of the portion may be released through the two second openings 62, thereby improving a stability of the display substrate 100 during and after the bending.

Based on this, two regions 403 of the encapsulation layer 40 corresponding to the two second openings 62 are separately recessed toward a side of the encapsulation layer 40 proximate to the base to form two second depressions 42, and the filler layer 50 includes two second filler portions 52 filled in the two second depressions 42. In this way, the bearing surface of the display substrate 100 located in the bending area BA is made relatively flat, so that after the wiring layer is manufactured, the short-circuit between adjacent metal wires in the wiring layer because of insufficient etching may be effectively ameliorated.

In some embodiments, as shown in FIG. 1, the display substrate 100 has the display area DA, an opening area OA at least partially surrounded by the display area DA, and a separation area MA located between the opening area OA and the display area DA. The opening area OA may be completely surrounded by the display area DA. Alternatively, the opening area OA may also be located at an edge of the display area DA and be partially surrounded by the display area DA. In addition, a shape of the opening area OA may be a circle, an ellipse, a semi-circle, a semiellipse, a star, a rhombus, a polygon, etc., which is not limited herein.

As shown in FIG. 7, the display substrate 100 further includes a first dam 71 and a second dam 72.

The first dam 71 is located in the separation area MA and between the base 10 and the encapsulation layer 40. The first dam 71 is disposed around the opening area OA.

The second dam 72 is located in the separation area MA and between the base 10 and the encapsulation layer 40. The second dam 72 is disposed around the opening area OA, and the second dam 72 is located between the first dam 71 and the opening area OA.

A region of the encapsulation layer 40 located on a side of the second dam 72 proximate to the opening area OA is recessed toward a side of the encapsulation layer 40 proximate to the base 10 to form the third depression 43 in the at least one depression 4, and the filler layer 50 includes the third filler portion 53 filled in the third depression 43; and/or, a region of the encapsulation layer 40 located on a side of the second dam 72 proximate to the display area DA is recessed toward a side of the encapsulation layer 40 proximate to the base 10 to form the fourth depression 44 in the at least one depression 4, and the filler layer 50 includes the fourth filler portion 54 filled in the fourth depression 44.

With this arrangement, the bearing surface of the display substrate 100 located in the separation area MA is made relatively flat, so that after the wiring layer is manufactured, the short-circuit between adjacent metal wires in the wiring layer because of insufficient etching may be effectively ameliorated.

In some examples, in the direction perpendicular to the base 10, a depth of the third depression 43 and a depth of the fourth depression 44 may both be approximately 4 μm.

For example, as shown in FIG. 7, the encapsulation layer 40 includes a first inorganic encapsulation layer 410, an organic encapsulation layer 411, and a second inorganic encapsulation layer 412 that are stacked. On the basis of this example, referring to FIGS. 1 and 7, regions of the encapsulation layer 40 located in the first depression 41, the second depression 42, and the third depression 43 may only include portions of the first inorganic encapsulation layer 410 and the second inorganic encapsulation layer 412 that are stacked. A region of the encapsulation layer 40 located in the fourth depression 44 may include only the portions of the first inorganic encapsulation layer 410 and the second inorganic encapsulation layer 412 that are stacked, or may also include portions of the first inorganic encapsulation layer 410, the organic encapsulation layer 411, and the second inorganic encapsulation layer 412 that are stacked. For example, in an example shown in FIG. 7, the region of the encapsulation layer 40 located in the fourth depression 44 includes a first region closer to the second dam 72 and a second region farther from the second dam. The first region only includes the portions of the first inorganic encapsulation layer 410 and the second inorganic encapsulation layer 412 that are stacked, and the second region includes the portions of the first inorganic encapsulation layer 410, the organic encapsulation layer 411, and the second inorganic encapsulation layer 412 that are stacked.

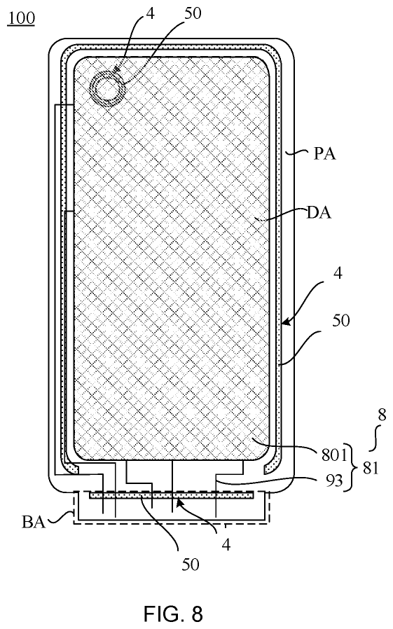

In some embodiments of the present disclosure, as shown in FIG. 8, the display substrate 100 further includes a first wiring layer 81. The first wiring layer 81 covers at least a portion of the surface of the filler layer 50 away from the base and a portion of the surface of the encapsulation layer 40 away from the base.

It will be noted that the first wiring layer 81 may be a wiring layer in the touch function layer. The bearing surface of the display substrate 100 provided in some embodiments of the present disclosure is relatively flat, so that after the first wiring layer 81 is manufactured, the short-circuit problem easily occurring between adjacent metal wires in the first wiring layer 81 because of insufficient etching may be effectively ameliorated.

The touch function layer may be manufactured by using the flexible multi-layer on cell (FMLOC) process. The touch function layer has a plurality of structural forms, for example, including but not limited to the following examples.

In some examples, as shown in FIG. 8, the first wiring layer 81 includes a plurality of touch electrodes 801 and a plurality of touch leads 92, and each touch electrode 801 is electrically connected to at least one touch lead 92.

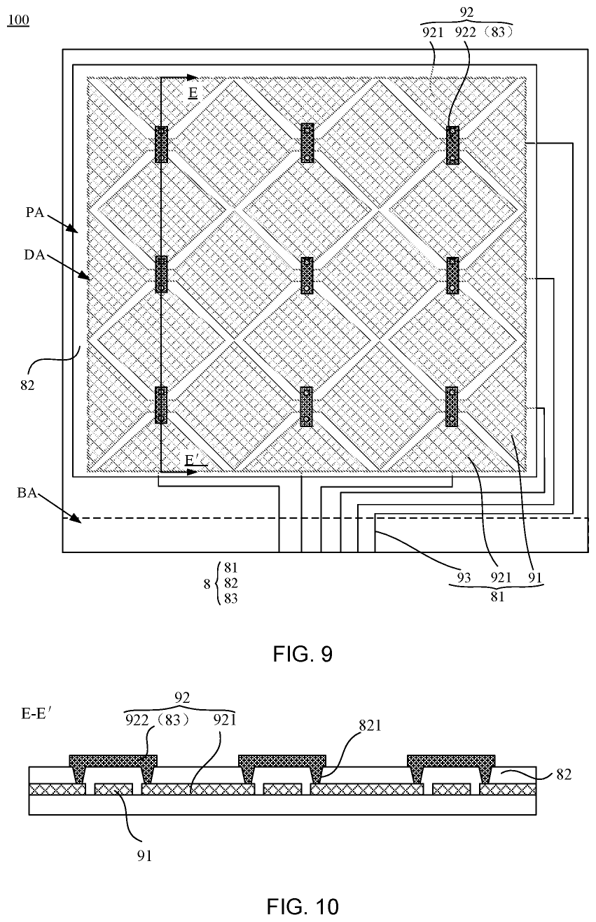

In some other examples, as shown in FIG. 9, the first wiring layer 81 includes a plurality of first touch electrodes 91 and a plurality of touch sub-electrodes 921 in a plurality of second touch electrodes 92. Each of the plurality of first touch electrodes 91 is an integrated structure. The plurality of touch sub-electrodes 921 are arranged in an array, and two adjacent touch sub-electrodes 921 located in a second touch electrode 92 are separated by a first touch electrode 91.

Based on this, the display substrate 100 further includes a fourth insulating layer 82 and a second wiring layer 83. The fourth insulating layer 82 has a plurality of third via holes 821 therein. The second wiring layer 83 includes a plurality of connection portions 922. As shown in FIG. 10, each connection portion 922 electrically connects two adjacent touch sub-electrodes 921 in a second touch electrode 92 through at least two third via holes 821, and there is an intersection region between an orthogonal projection of the connection portion 922 on the base and an orthogonal projection of the first touch electrode 91 on the base.

As shown in FIG. 9, the first wiring layer 81 further includes a plurality of touch leads 93, and each touch lead 93 is electrically connected to a first touch electrode 91 or a second touch electrode 92. In an implementation process of a touch function, since two adjacent touch sub-electrodes 921 separated by a first touch electrode 91 are connected by a connection portion 922 through at least two third via holes 821 in the fourth insulating layer 82, there is an overlapping region between the first touch electrode 91 and the connection portion 922. In addition, since the first touch electrode 91 and the connection portion 922 are insulated from each other, a capacitance will be formed in an intersection region between the first touch electrode 91 and the connection portion 922, and an original capacitance of the intersection region will be changed when a conductor (e.g., a finger) touches the intersection region. A position of a touch point may be obtained by detecting a change in the capacitance.

For example, components of at least one type in the plurality of first touch electrodes 91, the plurality of touch sub-electrodes 92, and the plurality of touch leads 93 cover at least a portion of the surface of the filler layer away from the base. In this way, the problem that the adjacent metal wires in the first wiring layer 81 are easily short-circuited because of insufficient etching is ameliorated, which is further beneficial to improve a stability of the touch function.

It will be noted that in FIG. 9, a region marked by a dashed box in the middle is a touch region, and the touch region corresponds to the display area DA of the display substrate 100. A peripheral area outside the region marked by the dashed box is a non-touch region, and the non-touch region corresponds to the peripheral area PA of the display substrate 100. The bending area BA is located in the non-touch region.

It will be seen from FIG. 9 that the plurality of first touch electrodes 91 and the plurality of touch sub-electrodes 921 may all be located in the touch region, and the plurality of touch leads 93 may all be located in the non-touch region of the display substrate 100. When the plurality of touch leads connected to the first touch electrodes 91 and the touch sub-electrodes 921 are led out from one or two sides of the touch region (e.g., touch leads connected to the first touch electrodes 91 in FIG. 9 are all led out from a right side in FIG. 9, and touch leads connected to the touch sub-electrodes 921 are all led out from a lower side in FIG. 9), depressions corresponding to the non-touch region on other sides (a left side and an upper side in FIG. 9) may not be filled because the depressions on other sides do not need to be provided with touch leads. It will be seen that in some embodiments of the present disclosure, specific shapes, positions and number of the filler portions may also be set according to an arrangement position of the first wiring layer.

For example, positions, having depressions, through which the touch leads pass in the bending area BA is also filled with the filler layer 5, which may reduce a risk of short circuit occurring in the touch leads 93 because of insufficient etching.

It will be noted that regions corresponding to the opening area OA and the separation area MA of the display substrate 100 are not shown in FIG. 9. When the display substrate 100 has the opening area OA and the separation area MA, the touch region may further include a portion corresponding to the separation area MA. In this case, since the filler layer may be filled in the depressions located in the separation area MA, the first touch electrode 91 and/or the touch sub-electrode 921 located at position(s) in the separation area MA may also be manufactured on a relatively flat bearing plane, which is beneficial to improve yields of the first touch electrode 91 and/or the touch sub-electrode 921.

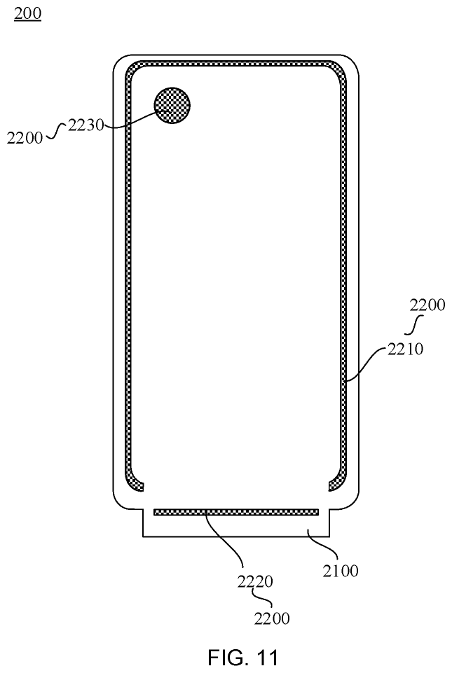

As shown in FIG. 11, some embodiments of the present disclosure provide a mask 200 for manufacturing the filler layer 50 in the display substrate 100 described above. The mask 200 includes a mask body 2100 and at least one light-transmitting portion 2200 disposed in the mask body 2100. Each light-transmitting portion 2200 is configured to allow light to pass through to enter at least one depression 4 in the display substrate 100.

For example, in an example shown in FIG. 11, a first light-transmitting portion 2210, a second light-transmitting portion 2220, and a third light-transmitting portion 2230 may be provided. The first light-transmitting portion 2210 is configured to allow light to pass through to enter the first depression 41 in FIG. 1, so as to cure a material of the filler layer in the first depression 41 to form the first filler portion 51; the second light-transmitting portion 2220 is configured to allow light to pass through to enter the second depression 42 in FIG. 1, so as to cure a material of the filler layer in the second depression 42 to form the second filler portion 52; and the third light-transmitting portion 2230 is configured to allow light to pass through to enter the third depression 43 and the fourth depression 44 in FIG. 1, so as to cure materials of the filler layer in the third depression 43 and the fourth depression 44 to form the third filler portion 53 and the fourth filler portion 54.

Therefore, the mask 200 in some embodiments of the present disclosure may realize a production of the filler layer in the above display substrate by adjusting a shape, size and position of each light-transmitting portion 2200.

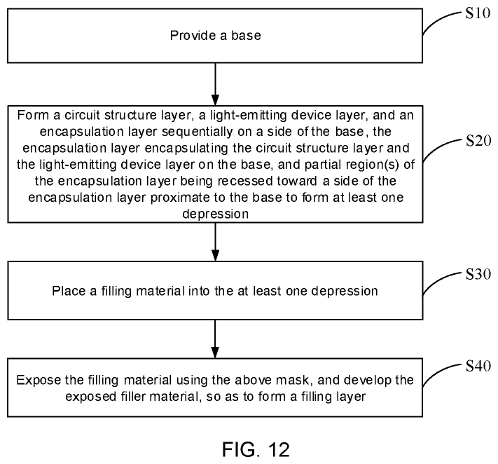

As shown in FIG. 12, some embodiments of the present disclosure provide a method of manufacturing a display substrate, and the method includes steps S10 to S40.

Referring to FIGS. 1, 2, and 12, in the method:

In S10, a base 10 is provided. A material of the base 10 may be, for example, polyimide, glass, or silicon substrate.

In S20, a circuit structure layer 20, a light-emitting device layer 30, and an encapsulation layer 40 are sequentially formed on a side of the base 10. The encapsulation layer 40 encapsulates the circuit structure layer 20 and the light-emitting device layer 30 on the base 10, and partial region(s) of the encapsulation layer 40 are recessed toward a side of the encapsulation layer 40 proximate to the base 10 to form at least one depression 4.

In S30, a filler material is placed in the at least one depression 4.

In S40, the filler material is exposed using the mask 200 and is developed, so as to form a filler layer 50.

In the display substrate 100 manufactured by the method of manufacturing the display substrate provided by some embodiments of the present disclosure, the filler layer 50 may be used to fill the at least one depression 4 in the encapsulation layer 40. For example, a surface of the filler layer 50 away from the base 10 and a portion, not covered by the filler layer 50, of a surface of the encapsulation layer 40 away from the base 10 (i.e., a bearing surface) may form a plane. In this way, in a subsequent process of manufacturing a wiring layer (e.g., touch lines in a touch function layer) on the encapsulation layer 40, a problem of insufficient etching of a portion of a metal thin film located in the depression 4 is not easy to occur. As a result, metal residues do not easily appear at that position, and short circuit between adjacent metal wires in the manufactured wiring layer is not easily caused, which is therefore beneficial to improve a yield of the display substrate 100.

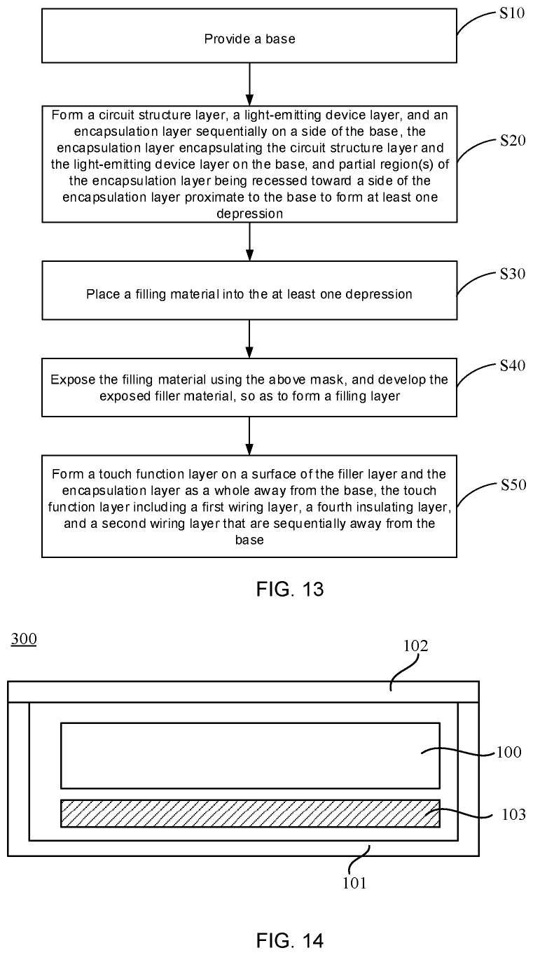

In some embodiments, referring to FIGS. 8, 9, 10, and 13, the method of manufacturing the display substrate further includes a step S50.

In S50, a touch function layer 8 is formed on a surface of the filler layer 50 and the encapsulation layer 40 as a whole away from the base 10. The touch function layer 8 includes a first wiring layer 81, a fourth insulating layer 82, and a second wiring layer 83 that are sequentially away from the base. Arrangements of the first wiring layer 81, the fourth insulating layer 82, and the second wiring layer 83 have been described in detail in the forgoing text, and thus will not be repeated herein again.

With this design, the manufactured display substrate 100 may realize a touch function. In addition, since the filler layer 50 is filled in the at least one depression 4 in the encapsulation layer 40, it is beneficial to ameliorate a short-circuit problem easily occurring between adjacent metal wires in the touch function layer 8 because of insufficient etching, and it is further beneficial to improve the stability of the touch function.

Referring to FIG. 14, some embodiments of the present disclosure provide a display apparatus 300. As shown in FIG. 14, the display apparatus 300 includes a display substrate 100, and the display substrate 100 may be an electroluminescent display substrate. The electroluminescent display substrate may be an organic light-emitting diode (OLED) display substrate or a quantum dot light-emitting diode (QLED) display substrate.

The display apparatus 300 provided by some embodiments of the present disclosure may be any product or component having a touch function and a display function, such as a display, a television, a digital camera, a mobile phone, a tablet computer or a digital photo frame.

With continued reference to FIG. 14, the display apparatus 300 may further include a housing 101, a cover plate 102, a circuit board 103, etc.

A longitudinal section of the housing 101 is U-shaped, and the display substrate 100, the circuit board 103 and other accessories are disposed in the housing 101. The circuit board 103 is disposed on a side of the display substrate 100, and the cover plate 102 is disposed on the other side of the display substrate 100. That is, the cover plate 102 is disposed on a side of the display substrate 100 facing away from the circuit board 103.

For example, the display substrate 100 may include the touch function layer 8 as described above, and an arrangement of the touch function layer 8 may enable the display apparatus to realize the touch function.

Since the display apparatus 300 provided by some embodiments of the present disclosure has the display substrate 100, it has same beneficial effects as the display substrate 100, and details will not be repeated herein.

The foregoing descriptions are merely specific implementations of the present disclosure, but the protection scope of the present disclosure is not limited thereto. Changes or replacements that any person skilled in the art could readily conceive of within the technical scope of the present disclosure shall be included in the protection scope of the present disclosure. Therefore, the protection scope of the present disclosure shall be subject to the protection scope of the claims.

1. A display substrate, comprising:
a base;
a circuit structure layer, a light-emitting device layer, and an encapsulation layer that are sequentially disposed on a side of the base, the encapsulation layer being configured to encapsulate the circuit structure layer and the light-emitting device layer on the base, and at least one region of the encapsulation layer being recessed toward a side of the encapsulation layer proximate to the base to form at least one depression; and
a filler layer filled in the at least one depression.

2. The display substrate according to claim 1, wherein the display substrate has a display area and a peripheral area located on at least one side of the display area; and the circuit structure layer includes:
a first metal layer including at least two first metal wires located in the peripheral area, the at least two first metal wires extending along a direction parallel to an interface between the display area and the peripheral area, and the at least two first metal wires being spaced apart in a direction perpendicular to the interface; and
a first insulating layer including at least two first insulating portions located in the peripheral area, each first insulating portion covering a first metal wire, and a first sub-opening being provided between two adjacent first insulating portions, wherein
a region of the encapsulation layer corresponding to the first sub-opening is recessed toward a side of the encapsulation layer proximate to the base to form a first depression in the at least one depression, and the filler layer includes a first filler portion filled in the first depression.

3. The display substrate according to claim 1, wherein the display substrate has a display area and a peripheral area located on at least one side of the display area; and the circuit structure layer includes:
a first metal layer including at least two first metal wires located in the peripheral area, the at least two first metal wires extending along a direction parallel to an interface between the display area and the peripheral area, and the at least two first metal wires being spaced apart in a direction perpendicular to the interface;
a first insulating layer including at least two first insulating portions located in the peripheral area, each first insulating portion covering a first metal wire, and a first sub-opening being provided between two adjacent first insulating portions;
a second metal layer including at least two second metal wires located in the peripheral area, and each second metal wire being disposed on a surface of one first insulating portion away from the base; and
a second insulating layer including at least two second insulating portions located in the peripheral area, each second insulating portion covering a second metal wire, and a second sub-opening that exposes the first sub-opening being provided between two adjacent second insulating portions, wherein
regions of the encapsulation layer corresponding to the second sub-opening and the first sub-opening are recessed toward a side of the encapsulation layer proximate to the base to form a first depression, and the filler layer includes a first filler portion filled in the first depression.

4. The display substrate according to claim 2, wherein the peripheral area includes a bending area located on a side of the display area;
the circuit structure layer further includes a third metal layer and a third insulating layer that are located in the bending area and sequentially disposed on the side of the base; the third metal layer includes at least one conductive connection portion; and the third insulating layer covers the at least one conductive connection portion, and at least two first via holes that expose the at least one conductive connection portion are provided in the third insulating layer;
the second metal layer further includes at least two third metal wires located in the bending area, the at least two third metal wires all extend along a direction pointing to the bending area from the display area, the at least two third metal wires are spaced apart in a direction perpendicular to an interface between the display area and the bending area, and two adjacent third metal wires are electrically connected to a conductive connection portion through two first via holes in the third insulating layer;
the second insulating layer further includes at least two third insulating portions, each third insulating portion covers a third metal wire, and a second opening is provided between two adjacent third insulating portions; and
a region of the encapsulation layer corresponding to the second opening is recessed toward a side of the encapsulation layer proximate to the base to form a second depression in the at least one depression, and the filler layer includes a second filler portion filled in the second depression.

5. The display substrate according to claim 43, wherein the peripheral area includes a bending area located on a side of the display area;
the circuit structure layer further includes a third metal layer and a third insulating layer that are located in the bending area and sequentially disposed on the side of the base; the third metal layer includes at least two conductive connection portion; the third insulating layer includes at least two fourth insulating portions, a fourth insulating portion covers a conductive connection portion, and a third opening is formed between two adjacent fourth insulating portions; at least two first via holes that expose a conductive connection portion are provided in a corresponding fourth insulating portion;
the second metal layer further includes at least two third metal wires located in the bending area, the at least two third metal wires all extend along a direction pointing to the bending area from the display area, and the at least two third metal wires are spaced apart in a direction perpendicular to an interface between the display area and the bending area;
the first insulating layer further includes at least two fifth insulating portions, a fifth insulating portion covers a third opening and portions, proximate to the third opening, of two fourth insulating portions adjacent to the third opening; the fifth insulating portion is provided with two second via holes therein that respectively expose two first via holes, each third metal wire is located on a surface of a fifth insulating portion away from the base, and a third metal wire is connected to two conductive connection portions through two second via holes and two first via holes;
the second insulating layer further includes at least two third insulating portions, each third insulating portion covers a third metal wire, and a second opening is provided between two adjacent third insulating portions; and
a region of the encapsulation layer corresponding to the second opening is recessed toward a side of the encapsulation layer proximate to the base to form a second depression in the at least one depression, and the filler layer includes a second filler portion filled in the second depression.

6. The display substrate according to claim 1, wherein the display substrate has a display area and a peripheral area located on at least one side of the display area; and the peripheral area includes a bending area located on a side of the display area; and
the circuit structure layer includes:
a third metal layer and a third insulating layer that are located in the bending area and sequentially disposed on the side of the base; the third metal layer including at least one conductive connection portion; and the third insulating layer covering the at least one conductive connection portion, and at least two first via holes that expose the at least one conductive connection portion being provided in the third insulating layer;
a second metal layer including at least two third metal wires located in the bending area, the at least two third metal wires all extending along a direction pointing to the bending area from the display area, the at least two third metal wires being spaced apart in a direction perpendicular to an interface between the display area and the bending area, and two adjacent third metal wires being electrically connected to a conductive connection portion through two first via holes in the third insulating layer; and
a second insulating layer including at least two third insulating portions, each third insulating portion covering a third metal wire, and a second opening being provided between two adjacent third insulating portions, wherein
a region of the encapsulation layer corresponding to the second opening is recessed toward a side of the encapsulation layer proximate to the base to form a second depression in the at least one depression, and the filler layer includes a second filler portion filled in the second depression.

7. The display substrate according to claim 1, wherein the display substrate has a display area and a peripheral area located on at least one side of the display area; and the peripheral area includes a bending area located on a side of the display area; the circuit structure layer includes:
a third metal layer and a third insulating layer that are located in the bending area and sequentially disposed on the side of the base; the third metal layer including at least two conductive connection portion; the third insulating layer including at least two fourth insulating portions, a fourth insulating portion covering a conductive connection portion, and a third opening being formed among two adjacent fourth insulating portions and the base; at least two first via holes that expose a conductive connection portion being provided in a corresponding fourth insulating portion;
a second metal layer including at least two third metal wires located in the bending area, the at least two third metal wires all extending along a direction pointing to the bending area from the display area, and the at least two third metal wires being spaced apart in a direction perpendicular to an interface between the display area and the bending area;
a first insulating layer including at least two fifth insulating portions, a fifth insulating portion covering a third opening and portions, proximate to the third opening, of two fourth insulating portions adjacent to the third opening; and the fifth insulating portion being provided with two second via holes therein that respectively expose two first via holes, each third metal wire being located on a surface of a fifth insulating portion away from the base, and a third metal wire being connected to two conductive connection portions through two second via holes and two first via holes; and
a second insulating layer including at least two third insulating portions, each third insulating portion covering a third metal wire, and a second opening being provided between two adjacent third insulating portions; wherein
a region of the encapsulation layer corresponding to the second opening is recessed toward a side of the encapsulation layer proximate to the base to form a second depression in the at least one depression, and the filler layer includes a second filler portion filled in the second depression.

8. The display substrate according to claim 5, wherein each third insulating portion further covers a fifth insulating portion.

9. The display substrate according to claims 4, wherein the display substrate has two second openings, and two regions of the encapsulation layer corresponding to the two second openings are separately recessed toward a side of the encapsulation layer proximate to the base to form two second depressions, and the filler layer includes two second filler portions filled in the two second depressions.

10. The display substrate according to any of claim 1, wherein the display substrate has a display area and an opening area at least partially surrounded by the display area, and a separation area located between the opening area and the display area; and
the display substrate further comprises:
a first dam located in the separation area and between the base and the encapsulation layer, and the first dam being disposed around the opening area; and
a second dam located in the separation area and between the base and the encapsulation layer, the second dam being disposed around the opening area, and the second dam being located between the first dam and the opening area, wherein
a region of the encapsulation layer located on a side of the second dam proximate to the opening area is recessed toward a side of the encapsulation layer proximate to the base to form a third depression in the at least one depression, and the filler layer includes a third filler portion filled in the third depression; and/or, a region of the encapsulation layer located on a side of the second dam proximate to the display area is recessed toward a side of the encapsulation layer proximate to the base to form a fourth depression in the at least one depression, and the filler layer includes a fourth filler portion filled in the fourth depression.

11. The display substrate according to claim 1, wherein a surface of the filler layer away from the base is flush with or substantially flush with a surface of the encapsulation layer away from the base.

12. The display substrate according to claim 1, wherein the display substrate further comprises a first wiring layer that covers at least a portion of the surface of the filler layer away from the base and at least a portion of the surface of the encapsulation layer away from the base.

13. The display substrate according to claim 12, wherein the first wiring layer includes:
a plurality of first touch electrodes and a plurality of touch sub-electrodes in a plurality of second touch electrodes, each first touch electrodes being an integrated structure, the plurality of touch sub-electrodes being arranged in an array, and two adjacent touch sub-electrodes located in a second touch electrode being separated by a first touch electrode; and
the display substrate further comprises:
a fourth insulating layer having a plurality of third via holes; and
a second wiring layer including a plurality of connection portions, each connection portion electrically connects two adjacent touch sub-electrodes in a second touch electrode through at least two third via holes, and an orthogonal projection of the connection portion on the base and an orthogonal projection of the first touch electrode on the base have an intersection region therebetween, wherein
the first wiring layer further includes a plurality of touch leads, and each touch lead is electrically connected to a first touch electrode or a second touch electrode; and components of at least one type in the plurality of first touch electrodes, the plurality of touch sub-electrodes, and the plurality of touch leads cover at least the portion of the surface of the filler layer away from the base.

14. A display apparatus, comprising:
the display substrate according to claim 1.

15. A mask for manufacturing the filler layer of the display substrate according to claims 1, the mask comprising:
a mask body, and
at least one light-transmitting portion disposed in the mask body, and each light-transmitting portion being configured to allow light to pass through to enter at least one depression in the display substrate.

16. A method of manufacturing a display substrate, the method comprising:
providing a base;
forming a circuit structure layer, a light-emitting device layer, and an encapsulation layer sequentially on a side of the base, the encapsulation layer encapsulating the circuit structure layer and the light-emitting device layer on the base, and partial region(s) of the encapsulation layer being recessed toward a side of the encapsulation layer proximate to the base to form at least one depression;
placing a filler material into the at least one depression; and
exposing the filler material using the mask according to claim 15 and developing the exposed filler material, so as to form a filler layer.

17. The method according to claim 16, further comprising:
forming a touch function layer on a surface of the filler layer and the encapsulation layer as a whole away from the base, the touch function layer including a first wiring layer, a fourth insulating layer, and a second wiring layer that are sequentially away from the base.

18. The display substrate according to claim 6, wherein the display substrate has two second openings, and two regions of the encapsulation layer corresponding to the two second openings are separately recessed toward a side of the encapsulation layer proximate to the base to form two second depressions, and the filler layer includes two second filler portions filled in the two second depressions.
